(19) United States
(12) Patent Application Publication
(10) Pub. No.: US 2012/0013414 A1
(43) Pub. Date: Jan. 19, 2012

(54) CRYSTAL OSCILLATOR CIRCUIT FOR ADJUSTING RESONANT FREQUENCY OF CRYSTAL OSCILLATOR

(75) Inventor: Guang-Feng OU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/848,103

(22) Filed: Jul. 31, 2010

(30) Foreign Application Priority Data
Jul. 14, 2010 (CN) 201010226391.0

(51) Int. Cl. H03B 5/30

(52) U.S. Cl. 331/158

(57) ABSTRACT

A crystal oscillator includes a clock generator, first and second capacitors, a crystal oscillator, a variable capacitance diode, and a voltage generating circuit. The crystal oscillator is connected between the input pin and the output pin of the clock generator, and connected between the first terminal of the first capacitor and the first terminal of the second capacitor. The variable capacitance diode is connected between the second terminal of the first capacitor and the second terminal of the second capacitor. The voltage generating circuit is connected between two terminals of the variable capacitance diode to supply different voltages for the variable capacitance diode to change a junction capacitance of the variable capacitance diode, to change a resonant frequency of the crystal oscillator.

### BACKGROUND

1. Technical Field

The present disclosure relates to crystal oscillator circuits and, particularly, to a crystal oscillator circuit for adjusting a resonant frequency of a crystal oscillator.

2. Description of Related Art

A clock signal is the dominant source of excessive electromagnetic interference (EMI) for many electronic devices. To detect which clock chip causes the excessive EMI, the signal frequency of each clock chip is changed alternately, and the clock chip whose frequency change shows the largest change in EMI will denote the source of the excessive EMI. However, the signal frequency of a clock chip is a multiple of a resonant frequency of a crystal oscillator, thus the frequency of an individual clock chip is difficult to change independently. Further, with the present technology, the resonant frequency in a typical crystal oscillator is also difficult to adjust. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a circuit diagram of an exemplary embodiment of a crystal oscillator circuit, the crystal oscillator circuit including a voltage generating circuit.

FIG. 2 is an equivalent circuit diagram of the crystal oscillator circuit excluding the voltage generating circuit of FIG. 1.

FIG. 3 is a graph of a resonant frequency of the crystal oscillator of FIG. 1 before and after the resonant frequency of the crystal oscillator is adjusted.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

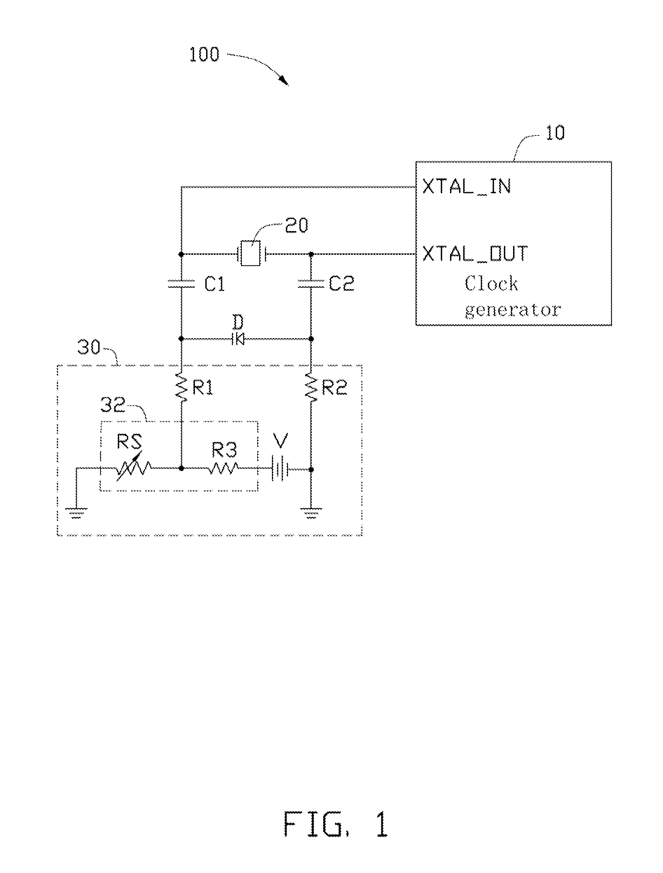

Referring to FIG. 1, an exemplary embodiment of a crystal oscillator circuit 100 includes a clock generator 10, a crystal oscillator 20, two capacitors C1 and C2, a variable capacitance diode D, and a voltage generating circuit 30. The voltage generating circuit 30 includes a direct current (DC) power V, a voltage division circuit 32, and two resistors R1 and R2. The voltage division circuit 32 includes a resistor R3 and a variable resistor RS. The resistor R3 and the variable resistor RS are connected in series between an anode of the DC power supply V and ground. A cathode of the DC power supply V is grounded. A cathode of the variable capacitance diode D is connected to a node between the resistor R3 and the variable resistor RS through the resistor R1, to receive a voltage from the voltage division circuit 32. An anode of the variable capacitance diode D is connected to the cathode of the DC voltage V through the resistor R2. The clock generator includes an input pin XTAL_IN and an output pin XTAL_OUT. The crystal oscillator 20 is connected between the input pin XTAL_IN and the output pin XTAL_OUT. The cathode of the variable capacitance diode D is connected to the input pin XTAL_IN through the capacitor C1. The anode of the variable capacitance diode D is connected to the output pin XTAL_OUT through the capacitor C2. In other embodiments, the resistors R1 and R2 can be omitted, and the cathode of the variable capacitance diode D is connected to the node between the resistor R3 and the variable resistor RS directly. The anode of the variable capacitance diode D is connected to the cathode of the DC power supply V directly.

Because in a variable capacitance diode the capacitance is inversely proportional to the square root of the applied voltage, a voltage between the anode and cathode of the variable capacitance diode D increases with a decrease in junction capacitance of the variable capacitance diode D, and vice versa. Therefore, when the voltage between the anode and cathode of the variable capacitance diode D is changed by adjusting a resistance of the variable resistance RS, the junction capacitance of the variable capacitance diode D is changed also, resulting in the resonant frequency of the crystal oscillator 20 being changed.

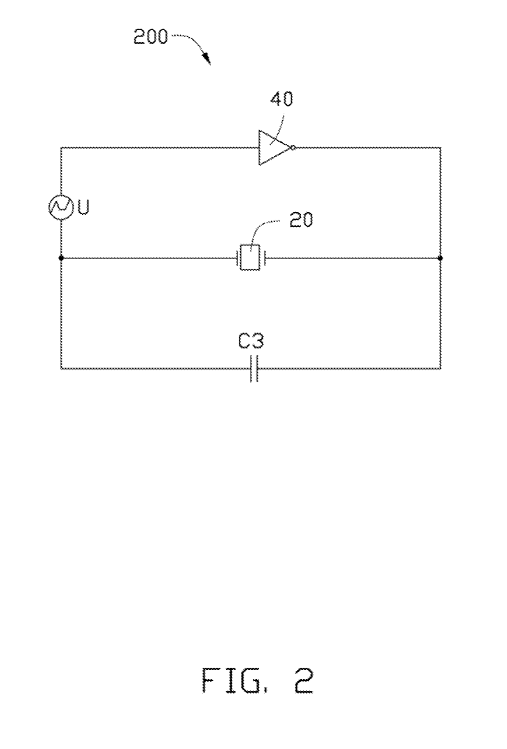

Referring to FIG. 2, an equivalent circuit 200 of the crystal oscillator circuit 100 excluding the voltage generating circuit 30 is shown. The equivalent circuit 200 includes an inverter 40, the crystal oscillator 20, a signal source U, and an equivalent capacitor C3. An input terminal of the inverter 40 is connected to a first terminal of the signal source U. The crystal oscillator 20 is connected between an output terminal of the inverter and a second terminal of the signal source U. The equivalent capacitor C3 is connected to the crystal oscillator 20 in parallel. Owing to properties of the clock generator 10, the input pin XTAL_IN and the output pin XTAL_OUT together are substantially equivalent to an inverter, therefore, in the embodiment, the clock generator 10 is equivalent to the inverter 40. The equivalent capacitor C3 is substantially equivalent to the variable capacitance diode D, and the capacitors C1 and C2. The signal source U is used to start the crystal oscillator 20.

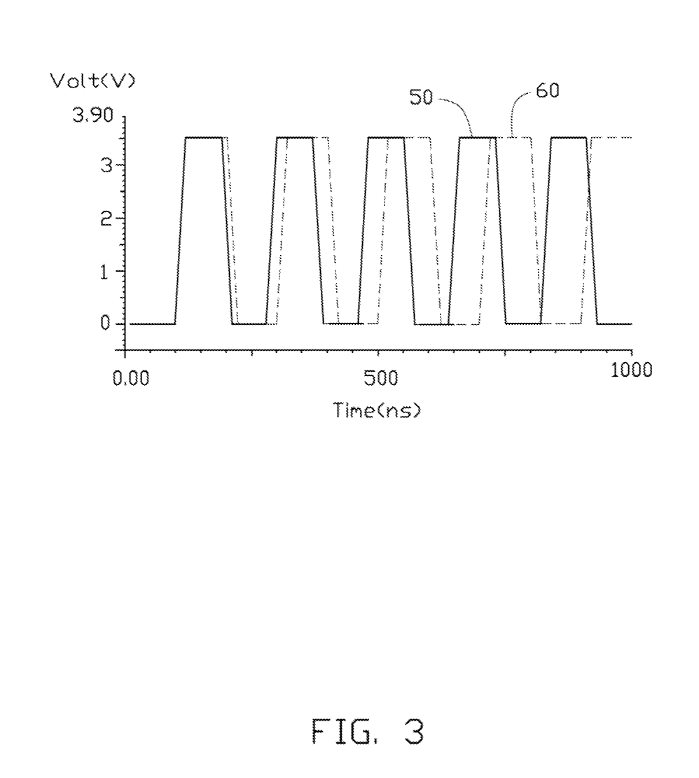

When resistance of the variable resistor RS is increased, the voltage at the node between the resistance R3 and the variable resistor RS increases, that is, the voltage between the anode and cathode of the variable capacitance diode D increases. The junction capacitance of the variable capacitance diode D decreases, that is, the capacitance of the equivalent capacitor C3 decreases. Referring to FIG. 3, a graph is shown of data obtained by simulating the equivalent circuit 200. The X-axis represents time in nanoseconds, and the Y-axis represents voltage of resonant frequency of the oscillator 20. A reference curve 50 is shown representing initial resonant frequency of the crystal oscillator 20. An adjusted curve 60 shows what happens to resonant frequency of the oscillator 20. According to the curves 50, 60, it is clear that the resonant frequency of the crystal oscillator 20 increases or decreases with decrease or increase of the resistance of the variable resistor RS respectively.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. A crystal oscillator circuit comprising:
a clock generator comprising an input pin and an output pin;
a first capacitor comprising a first terminal and a second terminal;
a second capacitor comprising a first terminal and a second terminal;
a crystal oscillator connected between the input pin and the output pin of the clock generator, and connected between the first terminal of the first capacitor and the first terminal of the second capacitor;
a variable capacitance diode connected between the second terminal of the first capacitor and the second terminal of the second capacitor; and
a voltage generating circuit connected between two terminals of the variable capacitance diode, to supply different voltages for the variable capacitance diode to change a junction capacitance of the variable capacitance diode, thereby to change a resonant frequency of the crystal oscillator.

2. The crystal oscillator circuit of claim 1, wherein the voltage generating circuit includes a direct current (DC) power supply and a voltage division circuit, the voltage division circuit is connected between the DC power supply and ground, to receive a voltage from the DC power supply to supply the different voltages for the variable capacitance diode.

3. The crystal oscillator circuit of claim 2, wherein the voltage division circuit comprises a first resistor and a variable resistor, the first resistor is connected to the variable resistor in series between an anode of the DC power supply and ground, a cathode of the DC power supply is grounded, a cathode of the variable capacitance diode is connected to a node between the first resistor and the variable resistor to receive the different voltages from the voltage division circuit, an anode of the variable capacitance diode is connected to the cathode of the DC power supply, the junction capacitance of the variable capacitance diode increases with a voltage between the anode and cathode of the variable capacitance diode decreasing, the junction capacitance of the variable capacitance diode decreases with a voltage between the anode and cathode of the variable capacitance diode increasing.

4. The crystal oscillator circuit of claim 3, wherein the voltage generating circuit further comprises a second resistor and a third resistor, the second resistor is connected between the cathode of the variable capacitance diode and the node between the first resistor and the variable resistor, the third resistor is connected between the anode of the variable capacitance diode and the cathode of the DC power supply.

5. A crystal oscillator circuit comprising:
a clock generator comprising an input pin and an output pin;
a crystal oscillator connected between the input pin and the output pin of the clock generator;
a first capacitor comprising a first terminal and a second terminal, the first terminal of the first capacitor connected to the input pin of the clock generator;
a second capacitor comprising a first terminal and a second terminal, the first terminal of the second capacitor connected to the output pin of the clock generator;
a variable capacitance diode connected between the second terminal of the first capacitor and the second terminal of the second capacitor; and
a voltage generating circuit connected in parallel to the variable capacitance diode, wherein when the voltage generating circuit voltage varies, the capacitance of the variable capacitance diode changes, thereby changing a resonant frequency of the crystal oscillator.
